(19) United States
(12) Patent Application Publication
(10) Pub. No.: US 2012/0164475 A1
(43) Pub. Date: Jun. 28, 2012

(54) COATED ARTICLE AND METHOD FOR MANUFACTURING COATED ARTICLE

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); KAO-YU LIAO, Tu-Cheng (TW); XIAO-QING XIONG, Shenzhen (CN)

(73) Assignees: HON HAI PRECISION INDUSTRY CO., LTD., Tu-Cheng (TW); HONG FU JIN PRECISION INDUSTRY (ShenZhen) CO.,LTD., Shenzhen City (CN)

(21) Appl. No.: 13/084,650

(22) Filed: Apr. 12, 2011

(30) Foreign Application Priority Data
Dec. 23, 2010 (CN) 201010602348.X

(51) Int. Cl. C23C 14/06; B32B 15/04; C23C 14/35

(52) U.S. Cl. 428/627; 428/450; 428/336; 204/192.15

(57) ABSTRACT

An coated article includes a substrate; an chromium layer deposited on the substrate; and a silicon-nitride layer deposited on the chromium layer opposite to the substrate.

### BACKGROUND

1. Technical Field

The exemplary disclosure generally relates to coated articles and a method for manufacturing the coated articles.

2. Description of Related Art

A mold made of stainless steel is used to mold low melting point material such as magnesium, magnesium alloy, aluminum, or aluminum alloy into coated articles. However, at high temperatures, a stainless steel mold may easily oxidize to form a Cr₂O₃ layer on the mold's surface. Additionally, with an increase in temperature, Fe ions and Ni ions in the coated article may diffuse into the Cr₂O₃ layer causing the Cr₂O₃ layer to appear cracked or to be shattered, which decreases the temperature oxidation resistance of the stainless steel substrate. In addition, the Cr₂O₃ layer may make the surface of the stainless steel mold rough, which may affect appearance of molded coated article, and decrease yield of molded coated article.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary coated article and method for manufacturing the coated article. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of coated article.

FIG. 2 is a schematic view of a magnetron sputtering coating machine for manufacturing the coated article in FIG. 1.

### DETAILED DESCRIPTION

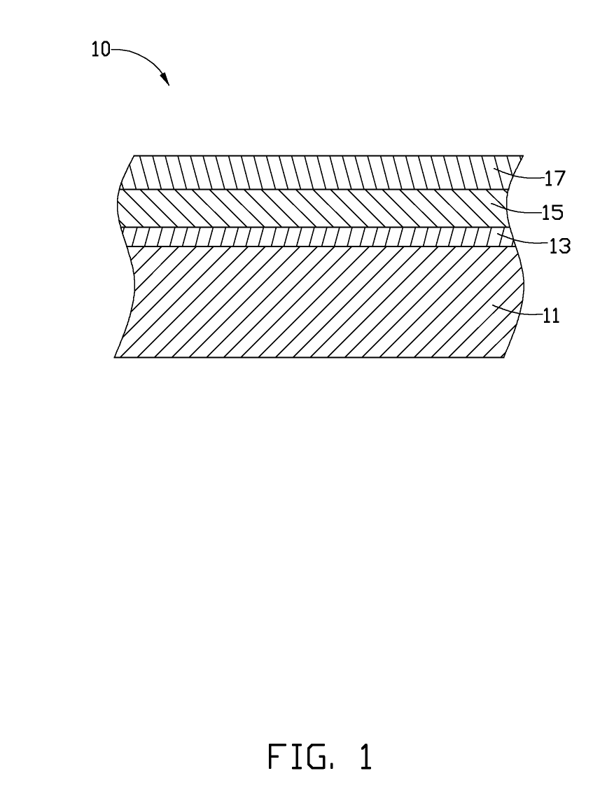

Referring to FIG. 1, an exemplary embodiment of an coated article 10 includes a substrate 11, a chromium layer 13 deposited on the substrate 11, and a silicon-nitride layer 15 (Si₃N₄) deposited on the side of the chromium layer 13 opposite to the substrate 11. The substrate 11 may be made of stainless steel, high speed steel or die steel. The chromium layer 13 has a thickness between 0.2 micrometers and 0.4 micrometers. The silicon-nitride layer 15 has a thickness between 0.3 micrometers and 0.6 micrometers. The chromium layer 13 and the silicon-nitride layer 15 may both be deposited by magnetron sputtering process. The coated article 10 is for manufacturing molds for forming low melting point material such as magnesium, magnesium alloy, aluminum, aluminum alloy.

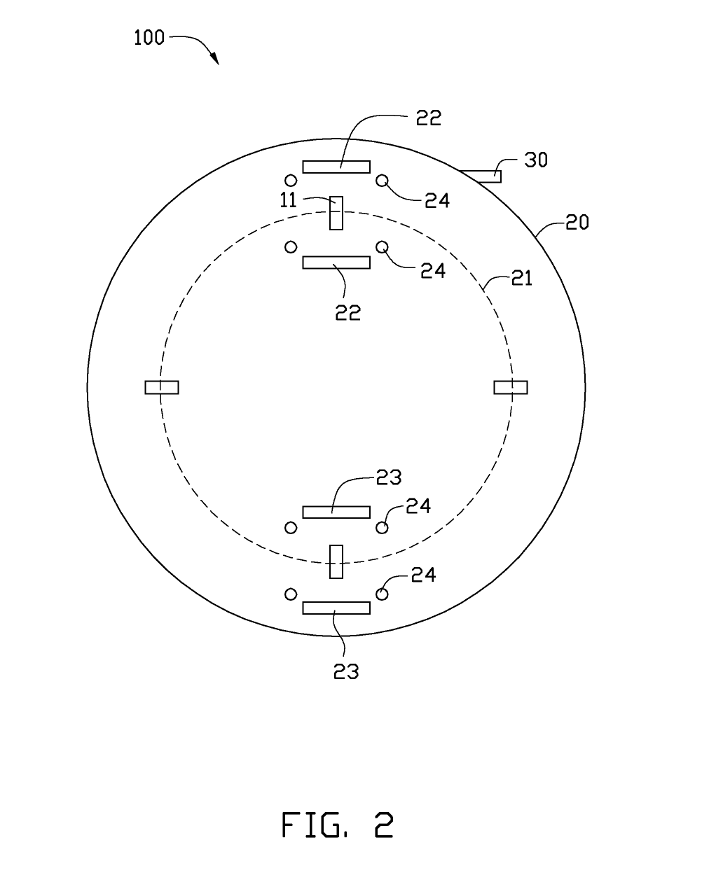

Referring to FIG. 2, a method for manufacturing the coated article 10 may include at least the following steps.

Providing a substrate 11. The substrate 11 may be made of stainless steel, high speed steel or die steel.

Pretreating the substrate 11, by washing it with a solution (e.g., Alcohol or Acetone) in an ultrasonic cleaner, to remove impurities and contaminations, such as grease, or dirt. The substrate 11 is then dried. The substrate 11 is then cleaned by argon plasma cleaning.

Providing a vacuum sputtering coating machine 100. The vacuum sputtering coating machine 100 includes a sputtering coating chamber 20 and a vacuum pump 30 connecting to the sputtering coating chamber 20. The vacuum pump 30 is used to pump the air out the sputtering coating chamber 20. The vacuum sputtering coating machine 100 further includes a rotating bracket 21, two first targets 22, two second targets 23 and a plurality of gas inlets 24. The rotating bracket 21 rotates the substrate 11 in the sputtering coating chamber 20 relative to the first targets 22 and the second targets 23. The first targets 22 face each other, and are respectively located on opposite sides of the rotating bracket 21. The second targets 23 face each other, and are respectively located on opposite sides of the rotating bracket 21. In this exemplary embodiment, the first targets 22 are chromium targets, the second targets 23 are silicon targets.

An chromium layer 13 is deposited on the substrate 11. The vacuum level inside the sputtering coating chamber 20 is set to about 8.0×10−3 Pa. The temperature in the sputtering coating chamber 20 is set between about 100° C. (Celsius degree) and about 150° C. Argon is fed into the sputtering coating chamber 20 at a flux between about 100 Standard Cubic Centimeters per Minute (sccm) and about 200 sccm from the gas inlets 24. The speed of the rotating bracket is set between about 0.5 revolutions per minute (rpm) and about 3 rpm. The first targets 22 in the sputtering coating chamber 20 are evaporated at a power between about 5 kW and about 10 kW. A bias voltage applied to the substrate 11 may be between about −100 volts and about −300 volts for between about 15 minutes and about 40 minutes, to deposit the chromium layer 13 on the substrate 11. Atomic chromium in the chromium layer 13 can react with atomic oxygen in the air to form a chromium-oxide layer. The chromium-oxide layer can prevent environmental oxygen from diffusing in the substrate 11, causing the coated article 10 to have high temperature oxidation resistance.

An silicon-nitride layer 15 is deposited on the chromium layer 13. The temperature in the sputtering coating chamber 20 is set between about 100° C. and about 150° C. Argon is fed into the sputtering coating chamber 20 at a flux between about 100 sccm and 200 sccm from the gas inlets 24. Nitrogen is fed into the sputtering coating chamber 20 at a flux between about 40 sccm and 120 sccm from the gas inlets 24. The second targets 23 in the sputtering coating chamber 20 are evaporated at a power between about 3 kW and about 5 kW. A bias voltage applied to the substrate 11 may be between about −50 volts and about −100 volts for between about 30 minutes and about 90 minutes, to deposit the silicon-nitride layer 15 on the chromium layer 13. The silicon-nitride layer 15 has a good compactness, which can prevent environmental oxygen from diffusing into the silicon-nitride layer 15. Thus, the silicon-nitride layer 15 can further cause the coated article 10 to have high temperature oxidation resistance. Additionally, the silicon-nitride layer 15 has a good corrosion resistance, thereby improving the corrosion resistance of the coated article 10.

### EXAMPLES

Experimental examples of the present disclosure are following.

### Example 1

1. Depositing the Chromium Layer 13 on the Substrate 11.

The vacuum level inside the sputtering coating chamber 20 is set to about 8.0×10−3 Pa. The temperature in the sputtering coating chamber 20 is set about 120° C. Argon is fed into the sputtering coating chamber 20 at a flux about 150 sccm from the gas inlets 24. The first targets 22 in the sputtering coating chamber 20 are evaporated at a power about 8 kW. A bias voltage applied to the substrate 11 may be between about −200 volts for about 25 minutes, to deposit the chromium layer 13 on the substrate 11.

2. Depositing the Silicon-Nitride Layer 15 on the Chromium Layer 13.

The temperature in the sputtering coating chamber 20 is set about 120° C. Argon is fed into the sputtering coating chamber 20 at a flux of about 150 sccm from the gas inlets 24. Nitrogen is fed into the sputtering coating chamber 20 at a flux of about 80 sccm from the gas inlets 24. The second targets 23 in the sputtering coating chamber 20 are evaporated at a power about 4 kW. A bias voltage applied to the substrate 11 may be about −50 volts for about 60 minutes, to deposit the silicon-nitride layer 15 on the chromium layer 13.

### Example 2

1. Depositing the Chromium Layer 13 on the Substrate 11.

The vacuum level inside the sputtering coating chamber 20 is set to about 8.0×10−3 Pa. The temperature in the sputtering coating chamber 20 is set about 120° C. Argon is fed into the sputtering coating chamber 20 at a flux about 150 sccm from the gas inlets 24. The first targets 22 in the sputtering coating chamber 20 are evaporated at a power about 10 kW. A bias voltage applied to the substrate 11 may be between about −200 volts for about 30 minutes, to deposit the chromium layer 13 on the substrate 11.

2. Depositing the Silicon-Nitride Layer 15 on the Chromium Layer 13.

The temperature in the sputtering coating chamber 20 is set about 120° C. Argon is fed into the sputtering coating chamber 20 at a flux about 150 sccm from the gas inlets 24. Nitrogen is fed into the sputtering coating chamber 20 at a flux about 120 sccm from the gas inlets 24. The second targets 23 in the sputtering coating chamber 20 are evaporated at a power about 5 kW. A bias voltage applied to the substrate 11 may be about −50 volts for about 90 minutes, to deposit the silicon-nitride layer 15 on the chromium layer 13.

### Example Results

To test the high temperature oxidation resistance of the example coated article 10, the coated article 10 is put in a furnace. The temperature inside the furnace is increased about 10° C. per minute until reaching 800° C. Then, the temperature inside the furnace is maintained at 800° C. for about 10 hours. The coated article 10 was removed from the furnace and had not peeled and/or oxidized. Thus, it is clear that the coated article 10 manufactured by above method has a good high temperature oxidation resistance.

The corrosion resistance of the example coated article 10 is tested by a ®5700 linear abrader with a force of 1 kg, a rubbing length of 2 inches and 25 circles per minute. After testing, the substrate was not exposed (i.e., the chromium and silicon nitride layers remained fully intact). Thus, it is clear that the coated article 10 manufactured by the above method has a good corrosion resistance.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An coated article, comprising:
a substrate;
a chromium layer deposited on the substrate; and
a silicon-nitride layer deposited on the chromium layer opposite to the substrate.

2. The coated article as claimed in claim 1, wherein the substrate is made of stainless steel, high speed steel or die steel.

3. The coated article as claimed in claim 1, wherein the chromium layer has a thickness between 0.2 micrometers and 0.4 micrometers.

4. The coated article as claimed in claim 1, wherein the silicon-nitride layer has a thickness between 0.3 micrometers and 0.6 micrometers.

5. The coated article as claimed in claim 1, wherein the chromium layer and the silicon-nitride layer are both deposited by magnetron sputtering process.

6. A method for manufacturing an coated article comprising steps of:
providing a substrate;
depositing a chromium layer on the substrate by magnetron sputtering; and
depositing an silicon-nitride layer on the chromium layer by magnetron sputtering.

7. The method of claim 6, wherein during depositing the chromium layer on the substrate, the substrate is retained in a sputtering coating chamber of a magnetron sputtering coating machine; the vacuum level inside the sputtering coating chamber is set to about 8.0×10−3 Pa; the temperature in the sputtering coating chamber is set between about 100° C. and about 150° C.; argon is fed into the sputtering coating chamber at a flux between about 100 sccm and about 200 sccm; a chromium target in the sputtering coating chamber is evaporated at a power between about 5 kW and about 10 kW; a bias voltage applied to the substrate is between about −100 volts and about −300 volts, for between about 15 minutes and about 40 minutes, to deposit the chromium layer on the substrate.

8. The method of claim 6, wherein during depositing the silicon-nitride layer on the chromium layer, the substrate is retained in a sputtering coating chamber of a magnetron sputtering coating machine; the temperature in the sputtering coating chamber is set between about 100° C. and about 150° C.; argon is fed into the sputtering coating chamber at a flux between about 100 sccm and 200 sccm; nitrogen is fed into the sputtering coating chamber at a flux between about 40 sccm and 120 sccm; a silicon target in the sputtering coating chamber is evaporated at a power between about 3 kW and about 5 kW; a bias voltage applied to the substrate is between about −50 volts and about −100 volts, for between about 30 minutes and about 90 minutes, to deposit the silicon-nitride layer on the chromium layer.
